(19) United States
(12) Patent Application Publication
(10) Pub. No.: US 2011/0126764 A1
(43) Pub. Date: Jun. 2, 2011

(54) GAS SUPPLY APPARATUS

(75) Inventors: Hsiang-Ping Sun, Taipei County (TW); Yu-Fan Chen, Taipei County (TW); Shun-Yuan Lo, Miaoli County (TW); Kai-Hsiang Hung, Taichung City (TW); Hsing-Hua Wu, Kaohsiung City (TW)

(73) Assignee: INDUSTRIAL TECHNOLOGY RESEARCH INSTITUTE, Hsinchu (TW)

(21) Appl. No.: 12/689,237

(22) Filed: Jan. 19, 2010

(30) Foreign Application Priority Data
Dec. 1, 2009 (TW) 98141043

(51) Int. Cl. C23C 16/505; C23C 16/00

(52) U.S. Cl. 118/723 I; 118/723 R

(57) ABSTRACT

A gas supply apparatus for introducing gases to a process chamber of a PECVD system is provided. The gas supply apparatus includes a gas inlet tube, a process gas pipe, a cleaning gas pipe, a remote plasma source (RPS) and a variable valve. The RPS is connected with a cleaning gas source, and the cleaning gas pipe is connected between the gas inlet tube and the RPS for introducing a cleaning gas from the RPS to the gas inlet tube. The process gas pipe is connected between the gas inlet tube and a process gas source for introducing a process gas to the gas inlet tube. The variable valve is installed in the gas inlet tube for closing a passage between the cleaning gas pipe and the gas inlet tube to prevent the process gas entering the cleaning gas pipe when the process gas is introduced to the process chamber.

### CROSS-REFERENCE TO RELATED APPLICATION

This application claims the priority benefit of Taiwan application serial no. 98141043, filed on Dec. 1, 2009. The entirety of the above-mentioned patent application is hereby incorporated by reference herein and made a part of specification.

### BACKGROUND OF THE INVENTION

1.Field of the Invention

The present invention relates to a gas supply apparatus used for a high-frequency plasma-enhanced chemical vapor deposition (PECVD) system.

2. Description of Related Art

Presently, a plasma-enhanced chemical vapor deposition (PECVD) system is a most important and a main thin-film deposition process in a thin-film solar cell industry. All of film layers required by the thin-film solar cell can be fabricated by the PECVD system. Generally, in a process chamber of the PECVD system, processes of depositing thin-films on a substrate and cleaning the process chamber are performed. Therefore, at least a process gas used for the thin-film deposition and a cleaning gas used for cleaning are introduced to the process chamber.

Recently, to satisfy a demand of a large area thin-film solar cell, a remote plasma source (RPS) is configured to the process chamber of the large area PECVD system for cleaning the chamber (for example, cleaning the thin-films accumulated on electrodes and chamber walls). Compared to a conventional method of using a radio frequency (RF) plasma source to excite a fluorine-containing gas source to generate plasma for cleaning, the RPS has a fast etching capability and a large area cleaning performance. Therefore, to effectively integrate the RPS in the high-frequency PECVD system, a mechanism design (for example, gas pipelines) thereof is an important key.

Presently, to improve a cleaning performance of the RPS, a diameter of an outlet pipe of the RPS is generally increased to increase a gas amount of the introduced cleaning gas, so as to achieve a predetermined performance. However, when the pipe diameter is increased, a parasitic capacitance of such place is accordingly increased, which may cause generation of local plasma, and accordingly the formed films may block the outlet of the RPS. Such phenomenon is obvious in the high-frequency PECVD system, so that a service lifespan of the RPS is reduced.

### SUMMARY OF THE INVENTION

The disclosure is directed to a gas supply apparatus, which can prevent an abnormal filming phenomenon generated at an outlet pipe of a remote plasma source (RPS), so as to increase a service lifespan of the RPS.

The disclosure provides a gas supply apparatus for introducing gases to a process chamber of a plasma-enhanced chemical vapor deposition (PECVD) system. The gas supply apparatus at least includes a gas inlet tube extended from external of the process chamber to internal of the process chamber, a process gas pipe, a cleaning gas pipe, a remote plasma source (RPS) and a variable valve. The RPS is connected to a cleaning gas source, and the cleaning gas pipe is connected between the gas inlet tube and the RPS for introducing a cleaning gas from the RPS to the gas inlet tube. The process gas pipe is connected between the gas inlet tube and a process gas source for introducing a process gas to the gas inlet tube. The variable valve is installed at a juncture of the gas inlet tube and cleaning gas pipe for closing a passage between the cleaning gas pipe and the gas inlet tube, so as to prevent the process gas from entering the cleaning gas pipe when the process gas is introduced into the process chamber.

According to the above description, in the gas supply apparatus of the disclosure, the process gas and the cleaning gas are introduced to the process chamber through a single inlet tube, and a variable valve is installed to prevent generating a parasitic capacitance, so as to avoid an abnormal filming phenomenon generated at a passage between the cleaning gas pipe and the gas inlet tube due to the parasitic capacitance, and meanwhile increase a deposition rate of the PECVD system, and improve a cleaning efficiency of the RPS in the process chamber under VHF excitation.

In order to make the aforementioned and other features of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A and FIG. 1B are schematic diagrams illustrating operations of a gas supply apparatus according to a first embodiment of the disclosure.

FIG. 2 is a schematic diagram illustrating an application of a gas supply apparatus of FIG. 1A (and FIG. 1B).

FIG. 3 is a schematic diagram illustrating a PECVD system according to a second embodiment of the disclosure.

### DESCRIPTION OF THE EMBODIMENTS

Embodiments are provided below with reference of drawings to fully describe the technique of the disclosure. Although the embodiments of the disclosure are illustrated by following drawings, the disclosure can still be implemented by different approaches, and is not limited to the provided embodiments. For clarity, sizes and relative sizes of components and regions in the drawings are not scaled.

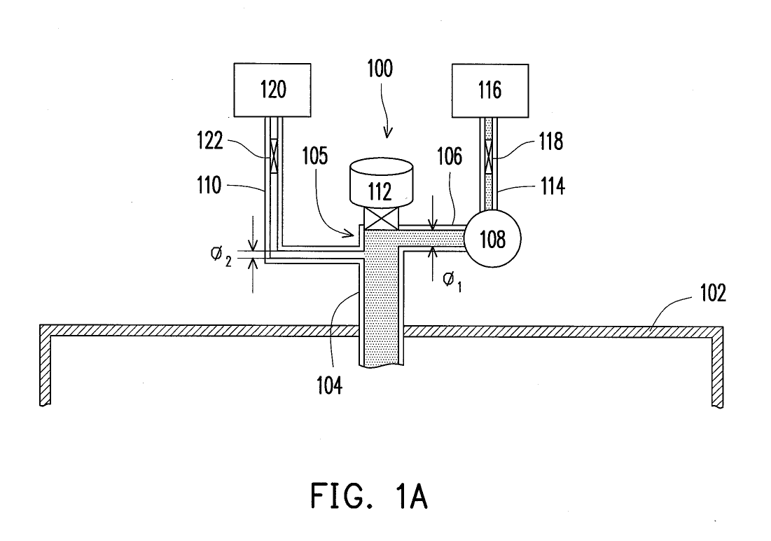

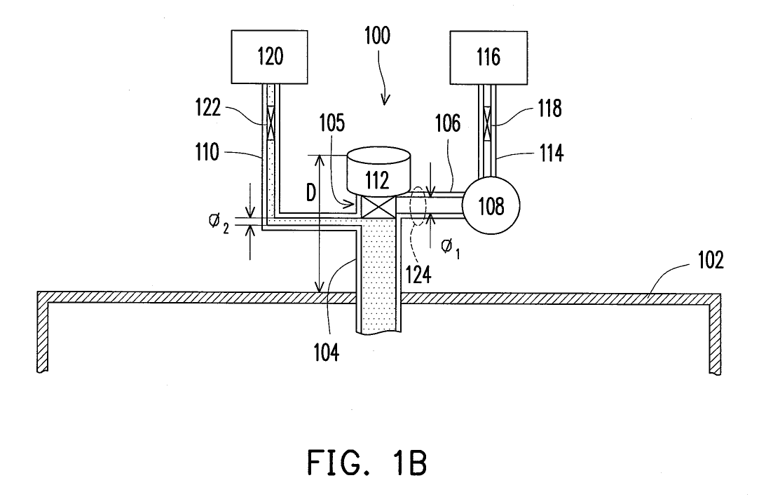

FIG. 1A and FIG. 1B are schematic diagrams illustrating operations of a gas supply apparatus according to a first embodiment of the disclosure.

Referring to FIG. 1A, the gas supply apparatus 100 of the first embodiment is used for introducing gases to a process chamber 102 of a plasma-enhanced chemical vapor deposition (PECVD) system. The gas supply apparatus 100 of FIG. 1 includes a gas inlet tube 104 extended from external of the process chamber 102 to internal thereof, a cleaning gas pipe 106, a remote plasma source (RPS) 108, a process gas pipe 110, and a variable valve 112. The gas inlet tube 104 is, for example, located at a position±30% from a center of the process chamber 102, and preferably at a position±10% from the center of the process chamber 102. It should be noticed that if the process chamber 102 is a chamber of a large area PECVD system, a plurality of gas inlet tubes 104 are generally used. Thus, the above position of the gas inlet tube 104 is merely suitable for the use of single gas inlet tube 104.

In the present embodiment, the RPS 108 is connected to a cleaning gas source 116 through a gas pipeline 114. Moreover, a valve 118 is generally installed in the gas pipeline 114 to control a cleaning gas (shown as “dots” in FIG. 1A) entering the RPS 108, wherein the cleaning gas is, for example, a gas selected from a gas group consisting of Ar, H₂, NF₃ and SF₆, or a compound or a mixture of the above gases. The cleaning gas pipe 106 is connected between the gas inlet tube 104 and the RPS 108 for introducing the cleaning gas from the RPS 108 to the gas inlet tube 104. As shown in FIG. 1A, when the valve 118 is opened, the cleaning gas flows into the RPS 108 to generate a high dissociation rate cleaning gas, and then flows into the cleaning gas pipe 106. Then, the cleaning gas enters the process chamber 102 through the gas inlet tube 104. Generally, a diameter φ₁ of the cleaning gas pipe 106 is greater than a diameter φ₂ of the process gas pipe 110. For example, the diameter φ₁ of the cleaning gas pipe 106 is 10 mm-60 mm, and preferably 25 mm-40 mm. The process gas pipe 110 is connected between the gas inlet tube 104 and a process gas source 120, and a valve 122 is generally installed in the process gas pipe 110 to control flowing of a process gas.

Then, referring to FIG. 1B, when the valve 122 is opened, the process gas (shown as “dots” in FIG. 1B) can enter the process chamber 102 through the gas inlet pipe 104, wherein the process gas is, for example, a gas selected from a gas group consisting of B₂H₆, CO₂, CO, GeH₄, H₂, He, N₂O, PH₃, SiH₄, SiF₄ and SiH₆, or a compound or a mixture of the above gases. When the process gas enters the process chamber 102, since the diameter φ₁ of the cleaning gas pipe 106 is obviously greater than the diameter φ₂ of the process gas pipe 110, the process gas probably enters the cleaning gas pipe 106. Therefore, in the first embodiment, the variable valve 112 is installed at a juncture 105 of the gas inlet tube 104 and cleaning gas pipe 106 for closing a passage 124 between them (the gas inlet tube 104 and cleaning gas pipe 106). The variable valve 112 is, for example, a valve fabricated by metal or stainless steel. Moreover, in the present embodiment, a distance D between the variable valve 112 and the process chamber 102 is, for example, 30 mm-100 mm.

Moreover, in the present embodiment, although there are one process gas source 120 and one cleaning gas source 116, the disclosure is not limited thereto. In case that there are a plurality of process gasses and/or a plurality of cleaning gasses, a plurality of process gas sources and/or a plurality of cleaning gas sources can be respectively connected to the gas inlet pipe 104, and the variable valve 112 is installed in each of the passages between the cleaning gas pipe and the gas inlet tube 104. In another embodiment, the process gas source and the cleaning gas source can also use a same type of gas, and in this case, the process gas source is equivalent to the cleaning gas source.

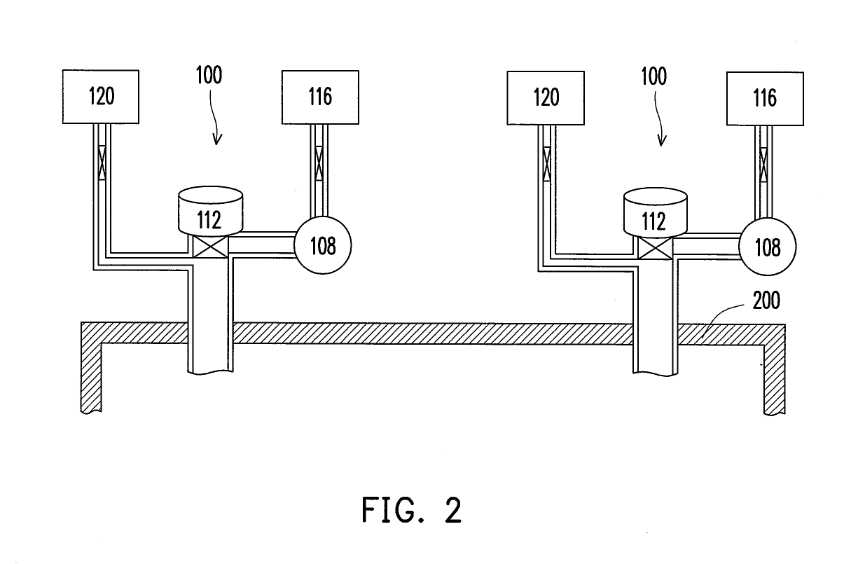

FIG. 2 is a schematic diagram illustrating an application of the gas supply apparatus of FIG. 1A (and FIG. 1B), wherein the same reference numerals in FIG. 1A, FIG. 1B and FIG. 2 denote the same elements.

Referring to FIG. 2, when a process chamber 200 is used for the PECVD system with a large area substrate, since the process chamber 200 has a large area itself, to guarantee a uniformity of the deposition and the cleaning processes, a plurality of gas supply apparatus 100 is used. In the present embodiment, two gas supply apparatus 100 are illustrated, though more gas supply apparatus 100 can still be configured according to a size of the process chamber 200.

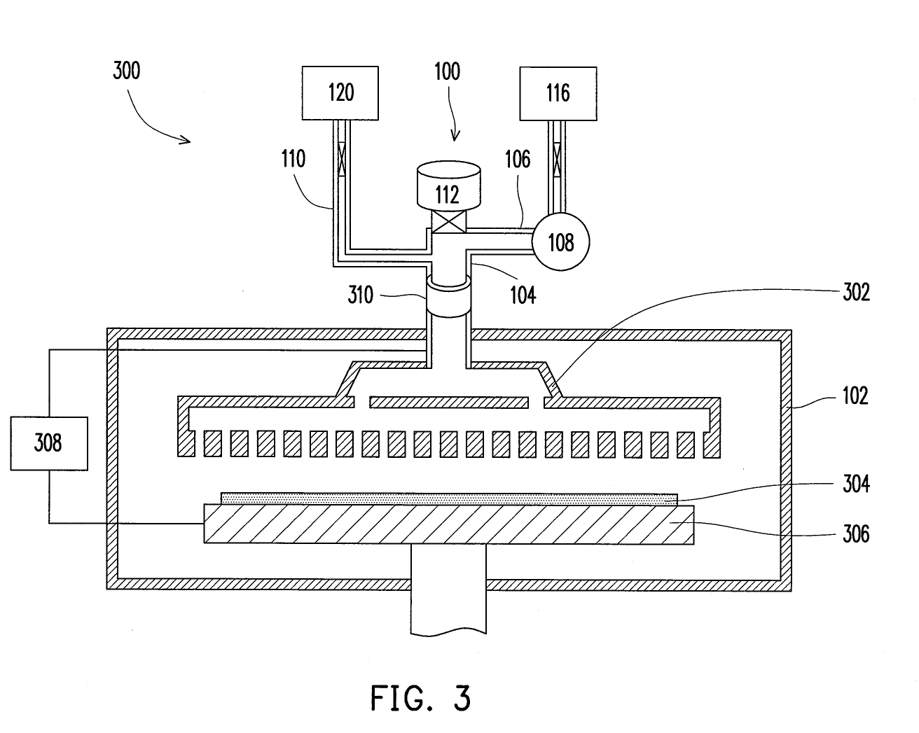

FIG. 3 is a schematic diagram illustrating a PECVD system according to a second embodiment of the disclosure, wherein the same reference numerals of the first embodiment and the second embodiment denote the same elements.

Referring to FIG. 3, a general PECVD system 300 includes the process chamber 102. The process chamber 102 includes a gas sprayer 302 connected to the gas inlet tube 104 of the gas supply apparatus 100, and a substrate base 306 used for carrying a substrate 304. After the process gas and/or the cleaning gas enter the process chamber 102 through the gas inlet tube 104, the gas sprayer 302 can evenly spray the process gas and/or the cleaning gas onto the substrate 304 disposed on the substrate base 306. The gas sprayer 302 and the substrate base 306 are generally an upper electrode and a lower electrode of the PECVD system 300. Therefore, the PECVD system 300 further includes a radio frequency (RF) power source 308, which is coupled between the gas sprayer 302 and the substrate base 306 in the process chamber 102 for forming plasma in the process chamber 102, and a frequency of the RF power source 308 is, for example, between 20 MHz and 100 MHz, and preferably between 25 MHz and 45 MHz. Since materials of the gas inlet pipe 104 and the gas sprayer 302 are generally metal or stainless steel, the RF power may enter the gas inlet tube 104 to generate the parasitic capacitance and cause a situation that a plenty of films and dusts are deposited at such place. To avoid the foregoing phenomena, in the present embodiment, the gas inlet tube 104 further includes a ceramic insulation portion 310 located between the process gas pipes 110 and the process chamber 102 and between the cleaning gas pipes 106 and the process chamber 102.

Besides the PECVD system 300 of the second embodiment, the persons having ordinary skill in the art should understand that the gas supply apparatus 100 can also be applied to other PECVD systems. Therefore, application of the gas supply apparatus 100 is not limited to the aforementioned embodiment.

In summary, in the gas supply apparatus of the disclosure, the process gas and the cleaning gas came from the RPS are introduced to the process chamber through a single inlet tube, and a variable valve is installed to prevent generating a parasitic capacitance or a situation that a plenty of films and dusts while thin-film deposition, so as to avoid an abnormal filming phenomenon generated at a passage between the cleaning gas pipe and the gas inlet tube due to the parasitic capacitance. Moreover, since the RPS is used in the gas supply apparatus of the disclosure, a cleaning efficiency can also be improved.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A gas supply apparatus, for introducing gases to a process chamber of a plasma-enhanced chemical vapor deposition (PECVD) system, the gas supply apparatus comprising:
a gas inlet tube, extended from external of the process chamber to internal of the process chamber;
a remote plasma source (RPS), connected to a cleaning gas source;
a cleaning gas pipe, connected between the gas inlet tube and the RPS, for introducing a cleaning gas from the RPS to the gas inlet tube;
a process gas pipe, connected between the gas inlet tube and a process gas source, for introducing a process gas to the gas inlet tube; and
a variable valve, installed at a juncture of the gas inlet tube and cleaning gas pipe, for closing a passage between the gas inlet tube and cleaning gas pipe, so as to prevent the process gas from entering the cleaning gas pipe when the process gas is introduced into the process chamber.

2. The gas supply apparatus as claimed in claim 1, wherein the gas inlet tube is located at a position±30% from a center of the process chamber.

3. The gas supply apparatus as claimed in claim 1, wherein a diameter of the cleaning gas pipe is greater than a diameter of the process gas pipe.

4. The gas supply apparatus as claimed in claim 1, wherein a diameter of the cleaning gas pipe is 10 mm-60 mm.

5. The gas supply apparatus as claimed in claim 1, wherein the variable valve comprises a valve fabricated by metal or stainless steel.

6. The gas supply apparatus as claimed in claim 1, wherein a distance between the variable valve and the process chamber is 30 mm-100 mm.

7. The gas supply apparatus as claimed in claim 1, wherein the process gas is a gas selected from a gas group consisting of B₂H₆, CO₂, CO, GeH₄, H₂, He, N₂O, PH₃, SiH₄, SiF₄ and SiH₆, or a compound or a mixture of the above gases.

8. The gas supply apparatus as claimed in claim 1, wherein the cleaning gas is a gas selected from a gas group consisting of Ar, H₂, NF₃ and SF₆, or a compound or a mixture of the above gases.

9. The gas supply apparatus as claimed in claim 1, wherein the gas inlet tube further comprises a ceramic insulation portion located between the process gas pipe and the process chamber and between the cleaning gas pipe and the process chamber.

10. The gas supply apparatus as claimed in claim 1, wherein the PECVD system comprising:
a gas sprayer, connected to the gas inlet tube;
a substrate base, for carrying a substrate; and
a radio frequency (RF) power source, coupled between the gas sprayer and the substrate base in the process chamber for forming plasma in the process chamber.

11. The gas supply apparatus as claimed in claim 10, wherein a frequency of the RF power source is between 20 MHz and 100 MHz.
